(19) United States
(12) Patent Application Publication
(10) Pub. No.: US 2007/0115812 A1
(43) Pub. Date: May 24, 2007

(54) Sequence numbers for multiple quality of service levels

(75) Inventor: David Anthony Hughes, Los Altos Hills, CA (US)

Correspondence Address: CARR & FERRELL LLP, 2200 GENG ROAD, PALO ALTO, CA, 94303, US

(73) Assignee: Silver Peak Systems, Inc.

(21) Appl. No.: 11/285,816

(22) Filed: Nov. 22, 2005

(51) Int. Cl. H04L 12/26; G01R 31/08; H04L 12/28; H04L 1/00; H04L 12/56

(52) U.S. Cl. 370/229; 370/395.21

(57) ABSTRACT

A system for providing communications using sequence numbers for multiple quality of service (QoS) levels includes a first network device. The first network device receives a data packet and determines a QoS level for the data packet. The first network device also determines a sequence number for the data packet based on the QoS level. The first network device then marks the data packet with the sequence number. The system also may include a second network device. The second network device receives from the first network device the data packet marked with the sequence number based on the QoS level of the data packet. The second network device determines an expected sequence number window based on the QoS level of the data packet. The second network device then determines whether the sequence number of the data packet is within the expected sequence number window for the QoS level.

### BACKGROUND

1. Technical Field

The present invention relates generally to communication networks and more particularly to providing communications using sequence numbers for multiple quality of service (QoS) levels.

2. Description of Related Art

The Internet provides access to information, goods, and services around the world. The Internet and other Internet Protocol (IP) routed networks carry data in P packets. FIG. 1 is an illustration of an IP packet 100 in the prior art. The IP packet 100 includes an IP header 110 with a type of service (TOS) field 130 and a payload 120. One limitation with the Internet is that the IP packet 100 is transmitted using unreliable service (also called best effort). Best effort means that the IP packet 100 can be dropped or discarded at any time without notification to source or destination of the IP packet 100. No guarantee is made that the IP packet 100 will be delivered to the destination or be delivered in the same order as transmitted (out of order delivery or delayed delivery). Additionally, no guarantee is made that the IP packet 100 will traverse the same route as other packets over the Internet.

To facilitate a limited form of delivery guarantee or quality of service (QoS), a source marks the IP packet 100 with a QoS level in the TOS field 130. QoS refers to the capability of a network to provide better and/or different services to selected packets, cells, frames, or datagrams over various technologies, including Frame Relay, Asynchronous Transfer Mode (ATM), and Ethernet. QoS typically provides different levels of service to the selected packets or cells, such as dedicated bandwidth, controlled jitter and latency (required by some real-time and interactive traffic), and improved packet loss characteristics. Some examples of real-time based traffic that benefits from QoS are voice over IP (VoIP), Instant Messaging (IM), multimedia video and audio, and data carried under a service-level agreement (SLA). QoS provides priority and possibly guaranteed delivery for the selected packets or cells from one point to another point; however, QoS in general does not ensure reliable end-to-end delivery.

FIG. 2 is an illustration of an Internet Protocol Security (IPSEC) packet 200 in the prior art. The IPSEC packet 200 includes an IP header 210 with a TOS field 240, an authentication header 220 with a sequence number 250, and a payload 230. IPSEC capabilities are used to encrypt and authenticate packets or cells. IPSEC implements a single range or set of monotonically increasing sequence numbers to track end-to-end delivery of IPSEC packets sent from a source to a destination. Additionally, IPSEC implements the sequence numbers to provide a security feature called “anti-replay” protection.

A replay attack occurs when a third party, which is not part of communications between a source and a destination, intercepts IPSEC packets sent from the source to the destination. The third party then later retransmits or “replays” the IPSEC packets to the destination in order to gain access to the destination or otherwise compromise the security of a system. The replay attack does not require that the third party decrypt the IPSEC packets, so strong encryption is not sufficient to prevent the replay attack. The destination prevents most replay attacks by dropping any IPSEC packets with IPSEC sequence numbers that fall outside of an anti-replay window (i.e., a range or set of expected or anticipated IPSEC sequence numbers).

One limitation of anti-replay protection in IPSEC becomes evident with multiple QoS levels. For example, QoS prioritization introduces reordering of IPSEC packets over an IP-routed communication network. The reordering appears to the destination of the IPSEC packets as a replay attack because QoS prioritization delays arrival of IPSEC packets with lower priority QoS levels at the destination. The destination in turn drops the delayed IPSEC packets because their sequence numbers are lower than what the anti-replay window allows.

FIG. 3 is an illustration of a system 300 for IPSEC communications using QoS and sequence numbers in the prior art. In this example, a source computer 310 transmits data flows 340 over a communication network 320 to a destination computer 330. The data flows 340 include a plurality of IPSEC packets. The IPSEC packets (e.g., IPSEC packets 342 and 344) include QoS levels 350 and sequence numbers 360. The destination computer 330 includes an expected sequence number window 370.

A hierarchy for the QoS levels 350 is illustrated: QoS level zero (0), QoS level one (1), and QoS level two (2). QoS level 0 receives the highest priority over the communication network 320 and QoS level 2 receives the lowest priority. The source computer 310 marks the IPSEC packets in the QoS levels 350 with different QoS levels. For example, the source computer 310 marks VOIP data with the QoS level 0 while the source computer 310 marks non real-time based data, such as email, with the QoS level 2.

The source computer 310 marks the IPSEC packets in the sequence numbers 360 from the same range or set of monotonically increasing sequence numbers. The destination computer 330 tracks the sequence numbers 360 of the IPSEC packets that the destination computer 330 receives with an anti-replay window (e.g., the expected sequence number window 370). In this example, the size of the expected sequence number window 370 is 4 (i.e., the destination computer 330 is tracking IPSEC packets with the sequence numbers 360 of 1, 2, 3, and 4). The size of the expected sequence number window 370 typically remains constant and the destination computer 330 sets the upper window bound of the expected sequence number window 370 to the highest of the sequence numbers 360 already seen. The destination computer 330 discards IPSEC packets with sequence numbers 360 under the lower window bound of the expected sequence number window 370.

In part due to QoS prioritization, the communication network 320 delivers the IPSEC packet 344 with the QoS level 0 to the destination computer 330 before the IPSEC packet 342 with the QoS level 1. The sequence number 360 of the IPSEC packet 344 (e.g., seven (7)) causes the destination computer 330 to increase the upper window bound of the expected sequence number window 370 to 7. The destination computer 330 now tracks sequence numbers 360 of 4, 5, 6, and 7.

After updating the expected sequence number window 370, the destination computer 330 drops the IPSEC packet 342 because the sequence number 360 of the IPSEC packet 342 (e.g. two (2)) is not within the expected sequence number window 370. The security benefit of the anti-replay window using the same range or set of sequence numbers for all QoS levels causes the destination computer 330 to drop IPSEC packets delayed due to QoS prioritization. Implementing a single set of sequences numbers degrades communications (e.g., by increasing dropped packets) between the source computer 310 and the destination computer 330.

The destination computer 330 can decrease the number of dropped IPSEC packets by providing each QoS level a separate IPSEC tunnel or session. The source computer 310 and the destination computer 330 then maintain separate state for each IPSEC tunnel assigned to a QoS level. However, with separate IPSEC tunnels for each QoS level, establishment and management of the IPSEC tunnels is difficult to administer and maintain. Additionally, providing separate IPSEC tunnels for each of the multiple QoS levels increases the amount of resources necessary in the source computer 310 and the destination computer 330 to maintain the required state for each separate IPSEC tunnel.

The destination computer 330 can also decrease the number of dropped IPSEC packets by increasing the size of the anti-replay window (e.g., the expected sequence number window 370). The destination computer 330 then accepts more of the IPSEC packets delayed and/or reordered due to QoS prioritization. However, increasing the size of the anti-replay window to accommodate QoS prioritization reduces the security of the anti-replay protection between the source computer 310 and the destination computer 330. With relaxed anti-replay protection, a third party that intercepts IPSEC packets sent from the source computer 310 to the destination computer 330 and later retransmits or “replays” the IPSEC packets can more easily compromise the security of the system 300.

### SUMMARY OF THE INVENTION

The invention addresses the above problems by providing a system, method, and software product for providing communications using sequence numbers for multiple QoS levels. The system includes a first network device. The first network device includes a first communication interface that communicates over a communication network and a first processor coupled to the first communication interface. The first processor receives a data packet and determines a QoS level for the data packet. The first processor determines a sequence number for the data packet based on the QoS level. The first processor then marks the data packet with the sequence number. The first processor may transmit the data packet over the communication network based on the QoS level. The first processor may also mark the data packet with the QoS level. The data packet may comprise an IP packet.

In some embodiments, the system includes a second network device. The second network device includes a second communication interface that receives from the first network device the data packet marked with the sequence number based on the QoS level of the data packet. The second network device also includes a second processor coupled to the second communication interface. The second processor determines an expected sequence number window based on the QoS level of the data packet. The second processor then determines whether the sequence number of the data packet is within the expected sequence number window for the QoS level.

The second processor may accept the data packet based on a positive determination that the sequence number is within the expected sequence number window for the QoS level. The second processor may also drop the data packet if the sequence number is not within the expected sequence number window for the QoS level. The expected sequence number window size may be based on the QoS level of the data packet.

Advantageously, the system provides greater control of communications of data packets with multiple QoS levels. The first network device marks the data packets with a sequence number for an associated QoS level. The system mitigates dropping data packets delayed due to QoS prioritization without sacrificing security in the system. Furthermore, the second network device matches the sequence number of the data packets to an expected sequence number window for the associated QoS level. The system provides enhanced QoS level based security through separate expected sequence number windows for the multiple QoS level. Additionally, the system may adjust the size of an expected sequence number window for an associated QoS level to provide greater security control in the system.

### BRIEF DESCRIPTION OF THE DRAWINGS

FIG. 1 is an illustration of an Internet Protocol (IP) packet in the prior art;

FIG. 2 is an illustration of an Internet Protocol Security (IPSEC) packet in the prior art;

FIG. 3 is an illustration of a system for IPSEC communications using quality of service (QoS) and sequence numbers in the prior art;

FIG. 4 is an illustration of a system for communications using sequence numbers for multiple QoS levels, in an exemplary implementation of the invention;

FIG. 5 is a flowchart for marking data using sequence numbers for multiple QoS levels, in an exemplary implementation of the invention;

FIG. 6 is a flowchart for receiving data using sequence numbers for multiple QoS levels, in an exemplary implementation of the invention;

FIG. 7 is a block diagram of a source network device for transmitting data using sequence numbers for multiple QoS levels, in an exemplary implementation of the invention; and

FIG. 8 is a block diagram of a destination network device for receiving data using sequence numbers for multiple QoS levels, in an exemplary implementation of the invention.

### DETAILED DESCRIPTION OF THE INVENTION

The embodiments discussed herein are illustrative of one example of the present invention. As these embodiments of the present invention are described with reference to illustrations, various modifications or adaptations of the methods and/or specific structures described may become apparent to those skilled in the art. All such modifications, adaptations, or variations that rely upon the teachings of the present invention, and through which these teachings have advanced the art, are considered to be within the scope of the present invention. Hence, these descriptions and drawings should not be considered in a limiting sense, as it is understood that the present invention is in no way limited to only the embodiments illustrated.

A system for providing communications using sequence numbers for multiple QoS levels includes a first network device (e.g., a source network device). The first network device includes a first communication interface that communicates over a communication network and a first processor coupled to the first communication interface. The first processor receives a data packet and determines a QoS level for the data packet. The first processor determines a sequence number for the data packet based on the QoS level. The first processor then marks the data packet with the sequence number.

The system may also include a second network device (e.g., a destination network device). The second network device includes a second communication interface that receives from the first network device the data packet marked with the sequence number based on the QoS level of the data packet. The second network device also includes a second processor coupled to the second communication interface. The second processor determines an expected sequence number window based on the QoS level of the data packet. The second processor then determines whether the sequence number of the data packet is within the expected sequence number window for the QoS level.

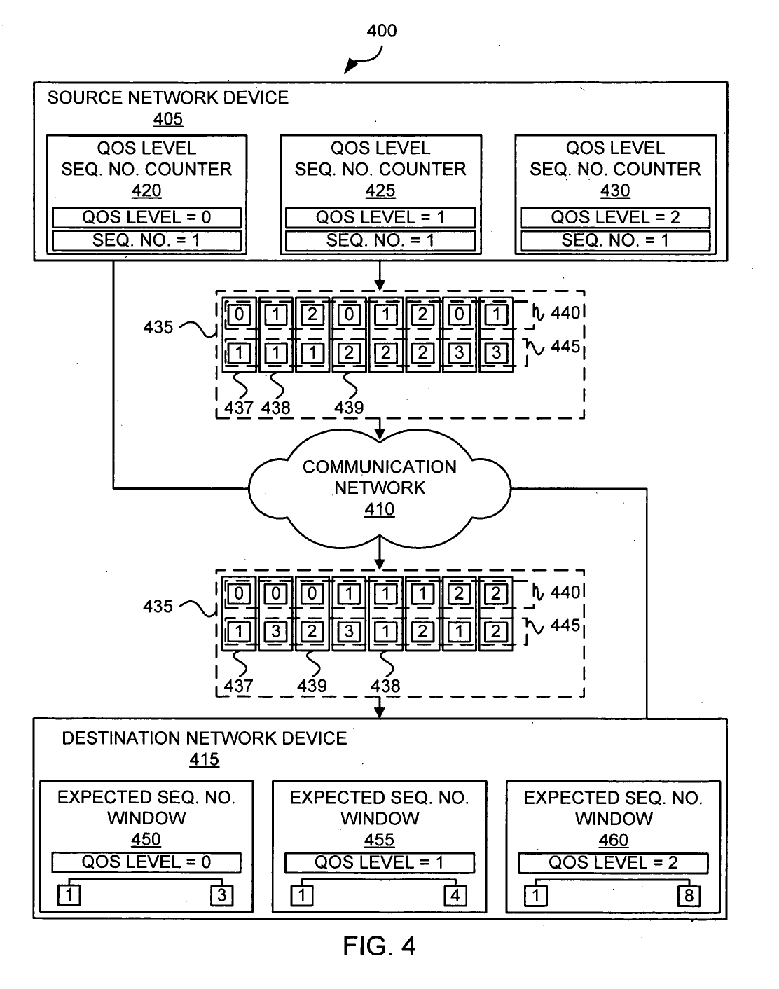

FIG. 4 is an illustration of a system 400 for communications using sequence numbers for multiple QoS levels, in an exemplary implementation of the invention. The system 400 includes a source network device 405, a communication network 410, and a destination network device 415. The source network device 405 includes QoS level sequence number counters 420, 425, and 430. The destination network device 415 includes expected sequence number windows 450, 455, and 460. The source network device 405 and the destination network device 415 are linked to the communication network 410.

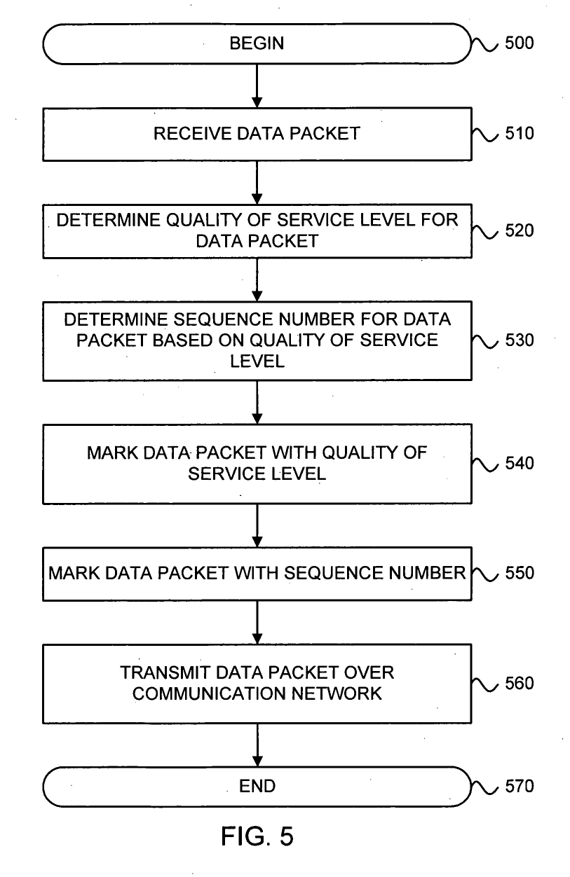

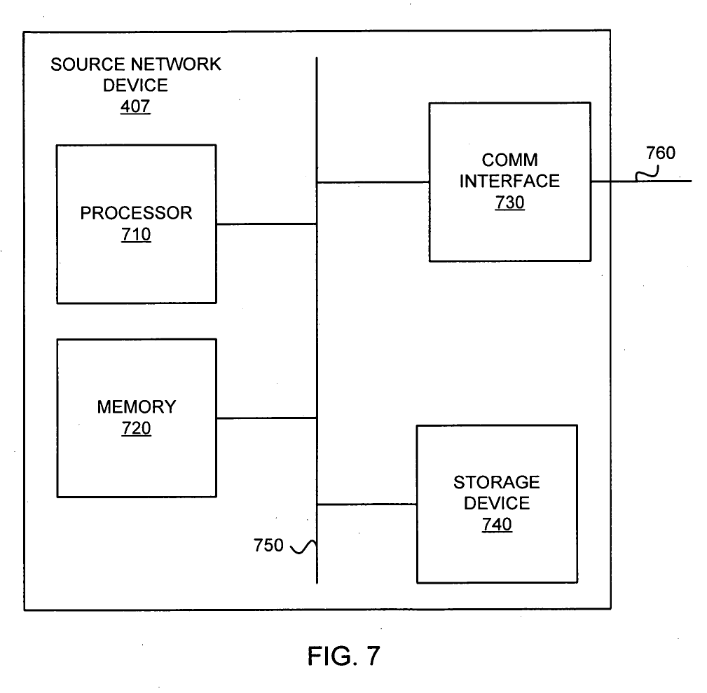

The source network device 405 comprises any hardware and/or software configured to determine a QoS level for a data packet, determine a sequence number for the data packet based on the QoS level of the data packet, and mark the data packet with the sequence number. One example of the source network device 405 is shown in FIG. 7. The operations of the source network device 405 are described further with respect to FIG. 5. Some examples of the source network device 405 are personal computers (PCs), laptops, network appliances, mainframes, and workstations.

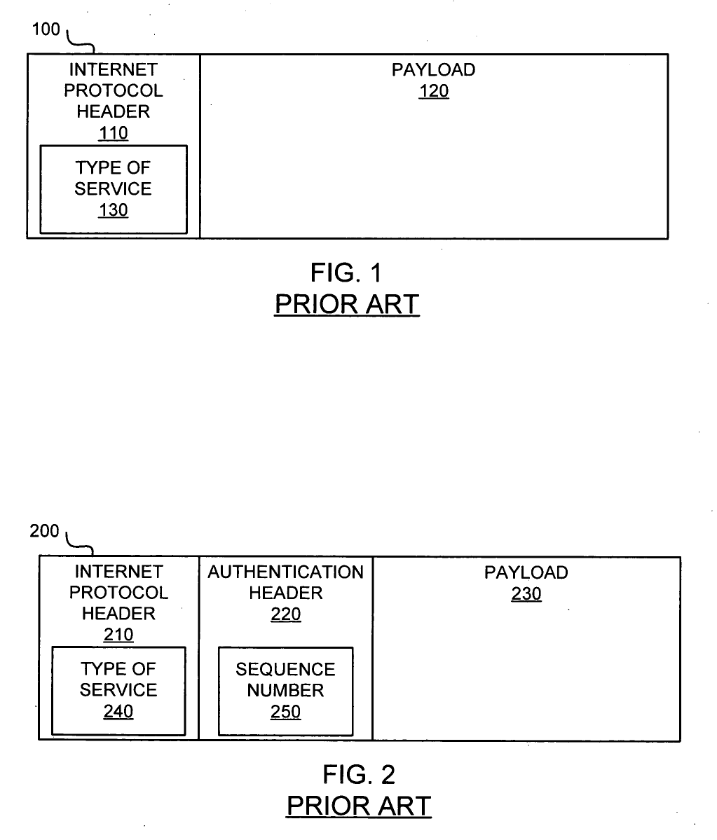

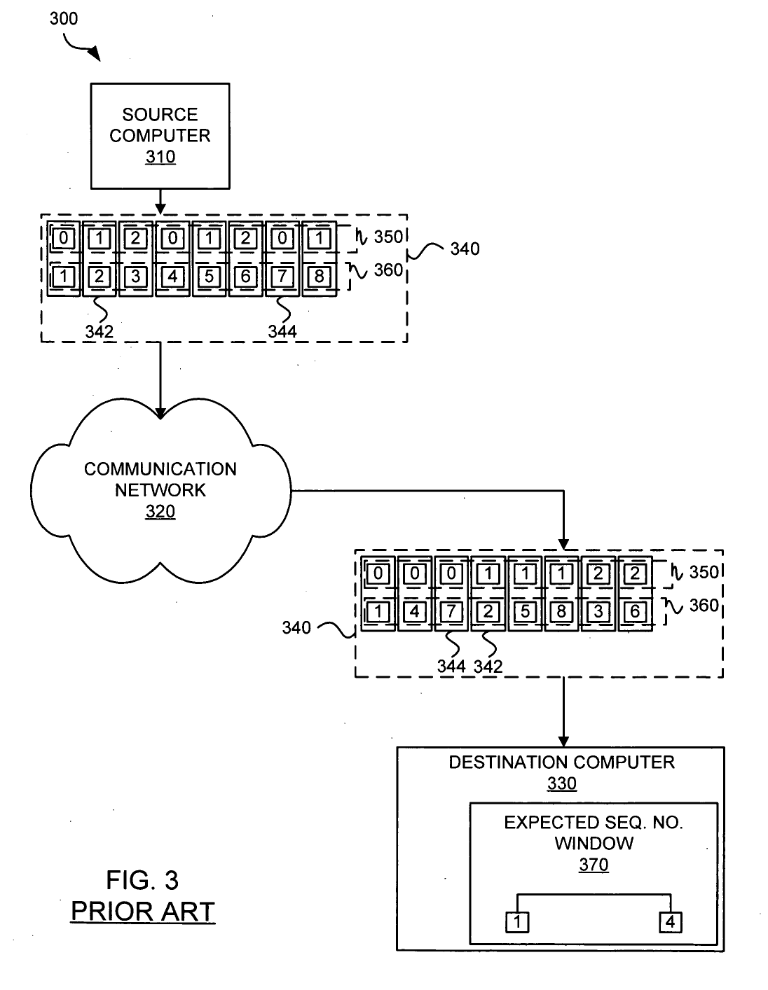

The data packet includes any packet, frame, cell, datagram, or other data format to communicate data over the communication network 410. A QoS level is any symbol, marking, and/or indicator in or associated with the data packet that can be used by the communication network 410 to implement a QoS scheme, such as a priority, a queue algorithm, bandwidth and traffic shaping, or any other per-hop treatment of the data packet. Some examples of QoS schemes are best-effort, differentiated service, and guaranteed service. Best-effort service is basic connectivity with no guarantees. Best-effort service is best characterized by first-in, first-out (FIFO) queues, which have no differentiation between the data packet and other data packets. Differentiated service enables the data packet to be treated better than other data packets (e.g., faster handling, more average bandwidth, and lower average loss rate). Guaranteed service provides an absolute reservation of communication network resources for the data packet. In some embodiments, the QoS level is marked in a header of the data packet (e.g., in the TOS field 130 of the IP packet 100 of FIG. 1).

A sequence number is any number, symbol, and/or character in or associated with the data packet that identifies an order for the data packet (or the data included in the data packet) in a message sequence. Some examples of a sequence number are numerical (e.g., 1, 2, 3 . . . ) and alphabetical (e.g., A, B, C . . . ). In some embodiments, the sequence number is attached to the data packet. In other embodiments, the sequence number is marked in a header of the data packet.

The QoS level sequence number counters 420, 425, and 430 comprise any hardware and/or software configured to track or maintain a sequence number for an assigned QoS level. One example of the QoS level sequence number counter 420 is a hardware counter. Another example of the QoS level sequence number counter 420 is a data structure provided by networking software of the source network device 405.

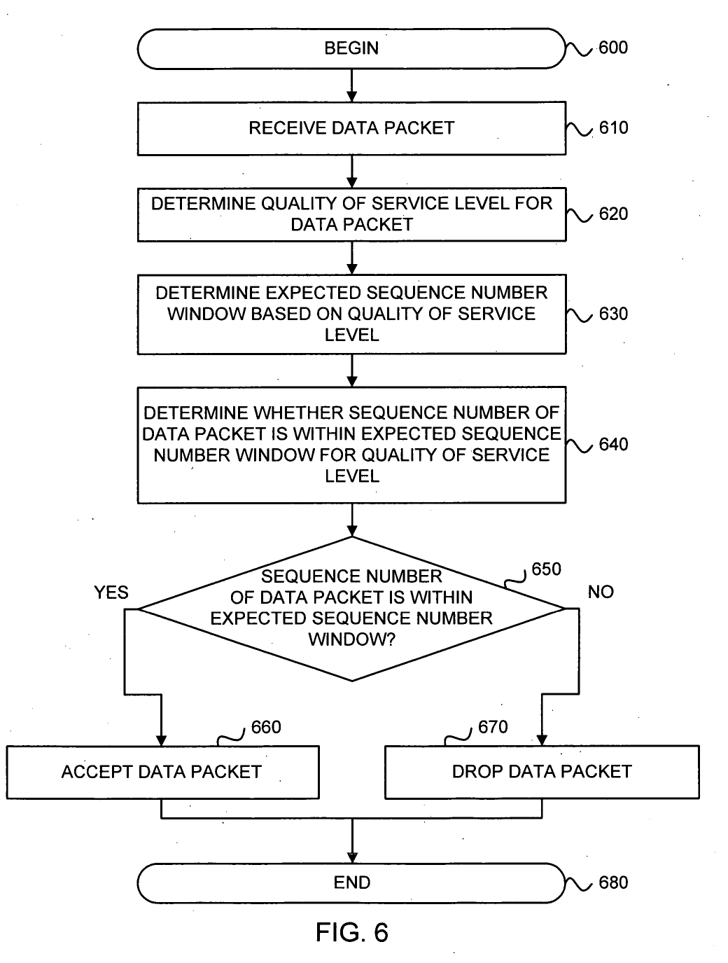

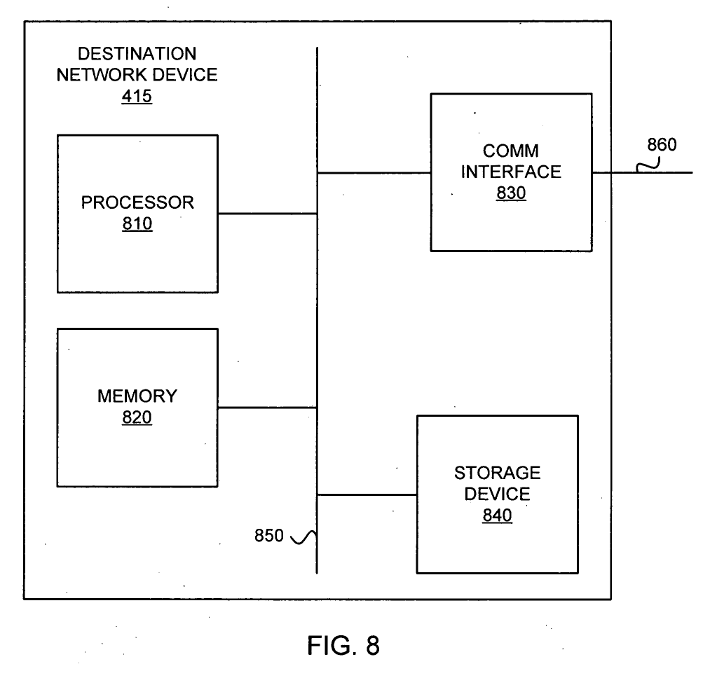

The destination network device 415 comprises any hardware and/or software configured to receive the data packet marked with the sequence number based on the QoS level for the data packet, determine an expected sequence number window based on the QoS level of the data packet, and determine whether the sequence number of the data packet is within the expected sequence number window for the QoS level. One example of the destination network device 415 is shown in FIG. 8. The operations of the destination network device 415 are further described with respect to FIG. 6. Some examples of the destination network device 415 are PCs, laptops, mainframes, and workstations.

The expected sequence number windows 450, 455, and 460 comprise any hardware and/or software configured to provide a range, group, or set of expected, anticipated, established, or projected sequence numbers for an assigned QoS level. One example of the expected sequence number window 450 is two hardware registers in the destination network device 415, a first hardware register for a lower window bound and a second hardware register for an upper window bound. Another example of the expected sequence number window 450 is a data structure provided by networking software of the destination network device 415.

Referring again to FIG. 4, data flows 435 include one or more IP packets (e.g., IP packet 437, IP packet 438, and IP packet 439). The IP packets include QoS levels 440 and QoS sequence numbers 445. The IP packet 437, for example, includes the QoS level 440 of zero (0) and the QoS sequence number 445 of one (1).

In this example, the source network device 405 marks the QoS levels 440 of the IP packets with a QoS level zero (0), a QoS level (1), or a QoS level (2). QoS level 0 is given higher priority over the communication network 410 than QoS level 1 and QoS level 2. The source network device 405 also marks the QoS sequence numbers 445 of the IP packets based on the QoS levels 440 of the individual IP packets. The source network device 405 then transmits the IP packets of the data flows 435 over the communication network 410 to the destination network device 415.

The communication network 410 reorders the IP packets in the data flows 435 in part due to QoS prioritization based on the QoS levels 440. For example, the IP packet 439 has a higher QoS level 440 (i.e., QoS level 0) than the IP packet 438 (i.e., QoS level 1). The IP packet 438 then arrives at the destination network device 415 after the IP packet 439, even though the IP packet 439 was transmitted after the IP packet 438.

The destination network device 415 determines the QoS levels 440 of the IP packets. The destination network device 415 then determines an expected sequence number window (e.g., the expected sequence number windows 450, 455, and 460) based on the QoS levels 440 of the IP packets. The destination network device 415 matches the QoS sequence numbers 445 of the IP packets to the particular expected sequence number window assigned to the QoS levels 440. For example, if the QoS sequence number 445 of the IP packet 439 is within the expected sequence number window 450, the destination network device 415 accepts the IP packet 439.

In some embodiments, the destination network device 415 determines the size (i.e., the lower window bound and the upper window bound) of the expected sequence number windows 450, 455, and 460 based on the QoS levels. For example, the illustration in FIG. 4 depicts that the lower window bound of the expected sequence number window 450 is one (1), and the upper window bound is three (3). The lower window bound of the expected sequence number window 460 is one (1), and the upper window bound is eight (8). IP packets given a higher priority QoS (e.g., the QoS level 0) typically arrive at the destination network device 415 sooner than IP packets given the lower priority QoS level 2, even if the IP packets given the lower priority QoS level 2 are transmitted earlier. The destination network device 415 may increase the size of the expected sequence number windows 450, 455, and 460 to compensate, for example, for the more variable delay of lower priority IP packets.

In other embodiments, the destination network device 415 determines the size of the expected sequence number windows 450, 455, and 460 based on the QoS level to provide enhanced security in the form of anti-replay protection. For example, the size of the expected sequence number window for a particular QoS level used to transmit sensitive data, such as usernames and password, can be adjusted (e.g., decreased) in order to provide greater QoS specific protection against duplicate or replayed IP packets later received by the destination network device 415.

Advantageously, the system 400 provides greater control of communications of data packets with multiple QoS levels. The system 400 mitigates dropping data packets delayed due to QoS prioritization without sacrificing security. The system 400 provides enhanced QoS level based security through separate expected sequence number windows for the multiple QoS level. Additionally, the system 400 may adjust the size of an expected sequence number window for an associated QoS level to provide greater security control of the associated QoS level in the system 400.

For example, the system 400 provides multiple QoS levels in a single IPSEC tunnel. The system 400 prevents unnecessary packet loss due to QoS prioritization without sacrificing anti-replay security in the single IPSEC tunnel. The system 400 also simplifies tunnel establishment and management in requiring only the single IPSEC tunnel for the multiple QoS levels. Furthermore, the system 400 may adjust the size of the anti-replay windows for separate QoS levels in the single IPSEC tunnel to ensure usability of the system 400 with adequate anti-replay protection and security for the separate QoS levels.

FIG. 5 is a flowchart for marking data using sequence numbers for multiple QoS levels, in an exemplary implementation of the invention. FIG. 5 begins in step 500. In step 510, the source network device 405 receives a data packet. In some embodiments, the source network device 405 generates the data packet. Alternatively, the source network device 405 may receive the data packet from another network device or computer (not shown) to be processed (e.g., transformed into an IPSEC tunnel packet) and transmitted to the destination network device 415.

In step 520, the source network device 405 determines a QoS level for the data packet. In one example, the source network device 405 determines a high priority QoS level (e.g., the QoS level 0 of FIG. 4) for a Voice over IP (VOIP) data packet implemented with real-time transport protocols (RTP) over user datagram protocol (UDP). In another example, the source network device 405 determines a low priority QoS level (e.g., the QoS level 2 of FIG. 4) for email transferred using Transmission Control Protocol/Internet Protocol (TCP/IP).

In step 530, the source network device 405 determines a sequence number for the data packet based on the QoS level of the data packet. If the source network device 405 determines the QoS level 0 for the data packet, the source network device 405 obtains the next sequence number from the QoS level sequence number counter 420 assigned to the QoS level 0. The source network device 405 then increments the QoS level sequence number counter 430.

Advantageously, for other types of data, such as email, the source network device 405 determines sequence numbers based on the QoS level of the data. For example, the source network device 405 obtains the next sequence number from the QoS level sequence number counter 430 for the QoS level 2 used for sending email. The source network device 405 then increments the QoS level sequence number counter 430.

Optionally, in step 540, the source network device 405 marks the data packet with the QoS level (e.g., in the QoS levels 440). The source network device 405 may not mark (or remark) data packets that already have QoS levels. In step 550, the source network device 405 marks the sequence number of the data packet (e.g., in the QoS sequence numbers 455). The source network device 450 may mark the sequence number in a header for the data packet, attach the sequence number to the data, or otherwise mark the data packet with the sequence number. In step 560, the source network device 405 transmits the data packet over the communication network 410 to the destination network device 415. FIG. 5 ends in step 560.

In some embodiments, the source network device 405 encrypts the data packet and encapsulates the data packet in an IPSEC tunnel packet. In step 540, the source network device 405 marks the IPSEC tunnel packet with the QoS level. In step 550, the source network device 405 marks the sequence number of the IPSEC tunnel packet (e.g., a sequence number in an encapsulated security payload header) based on the QoS level of the IPSEC tunnel packet. In another example, the source network device 405 may transform the data packet into an IPSEC transport packet. In this example, another computer or network device (not shown) marks the data packet with a QoS level. The source network device 405 marks the sequence number of the IPSEC transport packet (e.g., a sequence number in an authentication header) based on the QoS level of the data packet.

In some embodiments, separate IPSEC tunnels can be used for the multiple QoS levels. However, IPSEC tunnel establishment and management for the multiple QoS levels have significant overhead. The system 400 provides multiple QoS levels with sequence numbers in a single IPSEC tunnel. The system 400 allows efficient single tunnel establishment and management for multiple QoS levels.

FIG. 6 is a flowchart for receiving data using sequence numbers for multiple QoS levels, in an exemplary implementation of the present invention. FIG. 6 begins in step 600. In step 610, the destination network device 415 receives from the source network device 405 the data packet marked with the sequence number based on the QoS level of the data packet. In step 620, the destination network device 415 determines the QoS level of the data packet. For example, if the destination network device 415 receives an IPSEC tunnel packet, the destination network device 415 reads the QoS level from the TOS field in the IP header (e.g., the TOS field 130 in the IP header 110 of FIG. 1).

In step 630, the destination network device 415 determines an expected sequence number window (e.g., the expected sequence number windows 450, 455, 460) based on the QoS level of the data packet. In this example, if the destination network device 415 receives the IP packet 439 and the QoS level of the IP packet 439 is QoS level 0, the destination network device 415 matches the IP packet 439 to the expected sequence number window 450 assigned to the QoS level 0. In step 640, the destination network device 415 determines whether the sequence number for the data packet is within the expected sequence number window 450.

In step 650, if the sequence number is within the expected sequence number window, the destination network device 415 accepts the data packet in step 660. However, if the sequence number is not within the expected sequence number window, the destination network device 415 drops the data packet in step 670. Since the sequence number of the IP packet 439 is two (2) and within the window of 1 to 3 for the expected sequence number window 450, the destination network device 415 accepts the IP packet 439. FIG. 6 ends in step 680.

FIG. 7 is a block diagram of the source network device 405 for transmitting data using sequence numbers for multiple QoS levels, in an exemplary implementation of the invention. The source network device 405 includes a processor 710, a memory 720, a communication interface 730, and a storage device 740. The processor 710, the memory 720, the communication interface 730, and the storage device 740 are linked by a bus 750. The communication interface 730 is linked to a communication network (e.g., the communication network 410) by line 760.

FIG. 8 is a block diagram of the destination network device 415 for receiving data using sequence numbers for multiple QoS levels, in an exemplary implementation of the invention. The destination network device 415 includes a processor 810, a memory 820, a communication interface 830, and a storage device 840. The processor 810, the memory 820, the communication interface 830, and the storage device 840 are linked by a bus 850. The communication interface 830 is linked to a communication network (e.g., the communication network 410) by line 860.

The above-described functions can be comprised of instructions that are stored on storage media. The instructions can be retrieved and executed by a processor. Some examples of instructions are software, program code, and firmware. Some examples of storage media are memory devices, tape, disks, integrated circuits, and servers. The instructions are operational when executed by the processor to direct the processor to operate in accord with the invention. Those skilled in the art are familiar with instructions, processor(s), and storage media.

The above description is illustrative and not restrictive. Many variations of the invention will become apparent to those of skill in the art upon review of this disclosure. The scope of the invention should, therefore, be determined not with reference to the above description, but instead should be determined with reference to the appended claims along with their full scope of equivalents.

What is claimed is:

1. A method of providing communications using sequence numbers for multiple quality of service levels, the method comprising:
receiving a data packet;
determining a quality of service level for the data packet;
determining a sequence number for the data packet based on the quality of service level; and
marking the data packet with the sequence number.

2. The method of claim 1 further comprising transmitting the data packet over a communication network based on the quality of service level of the data packet.

3. The method of claim 1 further comprising marking the data packet with the quality of service level.

4. The method of claim 1 wherein the data packet comprises an Internet Protocol packet.

5. The method of claim 1 further comprising:
receiving the data packet marked with the sequence number based on the quality of service level of the data packet;
determining an expected sequence number window based on the quality of service level of the data packet; and
determining whether the sequence number of the data packet is within the expected sequence number window for the quality of service level.

6. The method of claim 5 further comprising accepting the data packet based on a positive determination that the sequence number of the data packet is within the expected sequence number window for the quality of service level.

7. The method of claim 5 further comprising dropping the data packet based on a negative determination that the sequence number of the data packet is within the expected sequence number window for the quality of service level.

8. The method of claim 5 wherein the expected sequence number window size is based upon the quality of service level.

9. A system for providing communications using sequence numbers for multiple quality of service levels, the system comprising:
in a first network device, a first communication interface configured to communicate over a communication network; and
in the first network device, a first processor coupled to the first communication device and configured to receive a data packet, determine a quality of service level for the data packet, determine a sequence number for the data packet based on the quality of service level, and mark the data packet with the sequence number.

10. The system of claim 9 wherein the first processor is further configured to transmit the data packet over the communication network based on the quality of service level.

11. The system of claim 9 wherein the first processor is further configured to mark the data packet with the quality of service level.

12. The system of claim 9 wherein the data packet comprises an Internet Protocol packet.

13. The system of claim 9 further comprising:
in a second network device, a second communication interface configured to receive from the first network device the data packet marked with the sequence number based on the quality of service level of the data packet; and
in the second network device, a second processor coupled to the second communication interface and configured to determine an expected sequence number window based on the quality of service level of the data packet and determine whether the sequence number of the data packet is within the expected sequence number window for the quality of service level.

14. The system of claim 13 wherein the second processor is further configured to accept the data packet based on a positive determination that the sequence number is within the expected sequence number window for the quality of service level.

15. The system of claim 13 wherein the second processor is further configured to drop the data packet based on a negative determination that the sequence number is within the expected sequence number window for the quality of service level.

16. The system of claim 13 wherein the expected sequence number window size is based on the quality of service level.

17. A software product for providing communications using sequence numbers for multiple quality of service levels, the software product comprising:
software operational when executed by a processor to direct the processor to receive a data packet, determine a quality of service level for the data packet, determine a sequence number for the data packet based on the quality of service level, and mark the data packet with the sequence number; and
a software storage medium operational to store the software.

18. The software product of claim 17 wherein the software is operational when executed by the processor to further direct the processor to transmit the data packet over a communication network based on the quality of service level of the data packet.

19. The software product of claim 17 wherein the software is operational when executed by the processor to further direct the processor to mark the data packet with the quality of service level.

20. The software product of claim 17 wherein the data packet comprises an Internet Protocol packet.

21. A software product for providing communications using sequence numbers for multiple quality of service levels, the software product comprising:
software operational when executed by a processor to direct the processor to receive a data packet marked with a sequence number based on a quality of service level of the data packet, determine an expected sequence number window based on the quality of service level of the data packet, and determine whether the sequence number of the data packet is within the expected sequence number window for the quality of service level; and
a software storage medium operational to store the software.

22. The software product of claim 21 wherein the software is operational when executed by the processor to further direct the processor to accept the data packet based on a positive determination that the sequence number of the data packet is within the expected sequence number window for the quality of service level.

23. The software product of claim 21 wherein the software is operational when executed by the processor to further direct the processor to drop the data packet based on a negative determination that the sequence number of the data packet is within the expected sequence number window for the quality of service level.

24. The software product of claim 21 wherein the expected sequence number window size is based upon the quality of service level.
